(19) United States
(12) Patent Application Publication
(10) Pub. No.: US 2024/0404910 A1
(43) Pub. Date: Dec. 5, 2024

(54) Semiconductor Device and Manufacturing Method Therefor

(71) Applicant: Nippon Telegraph and Telephone Corporation, Tokyo (JP)

(72) Inventors: Yusuke Araki, Musashino-shi, Tokyo (JP); Hideaki Matsuzaki, Musashino-shi, Tokyo (JP); Yuta Shiratori, Musashino-shi, Tokyo (JP)

(21) Appl. No.: 18/697,985

(22) PCT Filed: Nov. 5, 2021
(86) PCT No.: PCT/JP2021/040752

§ 371 Date: Apr. 2, 2024

(51) Int. Cl. H01L 23/367; H01L 23/31; H01L 23/538; H01L 25/00; H01L 25/065

(52) U.S. Cl. CPC H01L 23/367; H01L 25/0655; H01L 25/50; H01L 23/3107; H01L 23/5383

(57) ABSTRACT

A first heat transport structure formed to penetrate a molding resin layer is connected to a first extending portion of a first heat transport layer and a first heat dissipation plate formed on the molding resin layer. A second heat transport structure formed to penetrate the molding resin layer is connected to a second extending portion of a second heat transport layer and a second heat dissipation plate formed on the molding resin layer.

### TECHNICAL FIELD

The present invention relates to a semiconductor device and a method of manufacturing the same.

### BACKGROUND ART

In recent years, electronic devices such as smartphones have rapidly developed, and accordingly, there is an increasing demand for miniaturization and high performance of the electronic devices. On the back of this demand, a fan-out wafer level package (FOWLP) has attracted attention.

The FOWLP technology is a package technology in which a semiconductor chip, a passive component, and the like are integrated by a molding resin. An advantage of this package technology is that since a package substrate is unnecessary, the thickness can be reduced and the size can be reduced. Further, a wiring length between the semiconductor chips can be shortened, and a speed of a signal to be transmitted can be increased. Furthermore, by making a package area larger than a semiconductor chip area, terminals can be expanded to the outside of the chip, and a large number of input/output terminals can be secured.

However, in a FOWLP structure, since the semiconductor chip is sealed with the molding resin, heat dissipation has a problem. The thermal conductivity of the molding resin used for FOWLP is typically around 1 W/mK, and is smaller than about 170 W/mK, which is a value of Si typical of semiconductor chips, and about 400 W/mK, which is a value of copper typical of a material of heat dissipation plates (heat sinks). When the semiconductor chip is sealed with such a molding resin having a low thermal conductivity, heat generated in the semiconductor chip cannot be diffused, and the temperature of the semiconductor chip may exceed an allowable upper limit temperature.

In response to the above-described problem, studies have been made on heat dissipation characteristics of FOWLP (see, for example, Non Patent Literature 1 and Non Patent Literature 2). As a typical technique for improving the heat dissipation of the FOWLP, there is a technique of attaching a heat dissipation plate to the semiconductor chip. This will be described with reference to FIG. 3. In this semiconductor device, two semiconductor chips 302 and 303 having different thicknesses are sealed by a molding resin layer 305 on a wiring layer 301.

Since the thickness of the molding resin layer 305 is equal to that of the thickest semiconductor chip 302, the thickest semiconductor chip 302 is more exposed from the molding resin layer 305. A heat dissipation plate 307 is disposed immediately above the molding resin layer 305 and the thickest semiconductor chip 302. Further, the heat dissipation plate 307 and the semiconductor chip 303 are connected via a heat transport plate 306 formed of a heat transporter.

An integrated circuit 302a of the semiconductor chip 302 and an integrated circuit 303a of the semiconductor chip 303 are electrically connected to each other via wiring 301a formed in the wiring layer 301. Further, a terminal 301b is disposed below the wiring layer 301, and the wiring layer 301 is connected (mounted) to a printed circuit board 308 via the terminal 301b.

According to the above structure, heat generated in the semiconductor chip 302 and the semiconductor chip 303 is transferred to the heat dissipation plate 307 and diffused from the heat dissipation plate 307 into an atmosphere. Further, a part of the heat is transferred to the printed circuit board 308 via the wiring layer 301 and diffused from the printed circuit board 308 into the atmosphere. As a result, the heat dissipation of the FOWLP can be improved.

### CITATION LIST

### Non Patent Literature

Non Patent Literature 1: John H. Lau et al., “Warpage and Thermal Characterization of Fan-Out Wafer-Level Packaging”, IEEE Transactions on Components, Packaging and Manufacturing Technology, vol. 7, no. 10, pp. 1729-1738, 2017.
Non Patent Literature 2: A. Cardoso et al., “Thermally Enhanced FOWLP-Development of a Power-eWLB Demonstrator”, European Microelectronics Packaging Conference, ISBN 978-0-9568086 Feb. 2, 2015.

### SUMMARY OF INVENTION

### Technical Problem

However, in the above-described semiconductor device, for example, in a case where the semiconductor chip 302 having a large calorific value and the semiconductor chip 303 having a small calorific value are mounted, heat is transferred from the semiconductor chip 302 to the semiconductor chip 303 via the heat dissipation plate 307 and the heat transport plate 306. In such a state, the temperature of the semiconductor chip 303 may excessively rise, which may cause malfunction or failure.

To prevent such heat transfer, it is conceivable to connect an individual heat dissipation plate immediately above each semiconductor chip. However, in the FOWLP, in view of the fact that a wiring length is shortened by reducing the distance between the semiconductor chips in order to realize high speed of a transmission signal, it is not easy to dispose a plurality of heat dissipation plates having sizes corresponding to the calorific values of the semiconductor chips on the molding resin.

Further, it is also conceivable that heat is dissipated from the printed circuit board to the atmosphere via the wiring layer. In the case of a semiconductor chip having a large calorific value, it is difficult to obtain a sufficient amount of heat dissipation only by wiring that electrically connects the semiconductor chip and the printed circuit board. To overcome the difficulty, wiring intended for heat dissipation is formed in the wiring layer in addition to the wiring to be electrically connected, so that the amount of heat dissipation can be improved. However, when the wiring for the purpose of heat dissipation is provided as described above, the amount of heat dissipation is improved, but the area of the wiring layer increases, leading to an increase in size of the package. This goes against the demand for miniaturization of electronic devices. In addition, since the wiring intended for electrical connection and the wiring intended for heat dissipation are mixed in the wiring layer, the degree of freedom of chip layout and wiring is suppressed.

The present invention has been made to solve the above problems, and an object of the present invention is to improve heat dissipation without increasing the size of the package, without suppressing the degree of freedom of chip layout and wiring, and without causing malfunction or failure.

### Solution to Problem

A semiconductor device according to the present invention includes: a wiring layer in which wiring is formed; a semiconductor chip disposed on the wiring layer; an integrated circuit formed on a main surface of the semiconductor chip, the main surface facing a side of the wiring layer, and connected to the wiring; a heat transport layer formed on a surface of the semiconductor chip on which the integrated circuit is not formed, and further including a heat transporter including an extending portion extending on the wiring layer and formed on the semiconductor chip; a molding resin layer made of a molding resin for molding the semiconductor chip covered with the heat transport layer on the wiring layer; a heat dissipation plate formed on the molding resin layer; and a heat transport structure formed to penetrate the molding resin layer, and including a heat transporter that thermally connects the extending portion of the heat transport layer and the heat dissipation plate.

Further, a method of manufacturing a semiconductor device according to the present invention includes: a first step of fixing a semiconductor chip having an integrated circuit formed on a main surface onto a support substrate with the surface on which the integrated circuit is formed; a second step of forming a layer including a heat transporter on the support substrate to which the semiconductor chip is fixed; a third step of forming a layer including a heat transporter on the support substrate and then molding the semiconductor chip with a molding resin to form a molding resin layer; a fourth step of separating the support substrate and the molding resin layer; a fifth step of separating the support substrate and the molding resin layer, then removing a part of the layer formed to cover a back surface of the molding resin layer on a side where the integrated circuit is formed, and forming a heat transport layer including an extending portion formed on a surface of the semiconductor chip other than the surface on the side where the integrated circuit is formed and further extending on the back surface of the molding resin layer; a sixth step of forming a heat transport structure including a heat transporter thermally connected to the extending portion of the heat transport layer in a state of being molded in the molding resin layer; a seventh step of forming a state in which the semiconductor chip is disposed on a wiring layer including wiring, the integrated circuit is connected to the wiring, and the semiconductor chip is molded with the molding resin layer on the wiring layer; and an eighth step of forming a heat dissipation plate thermally connected to the heat transport structure on the molding resin layer.

### Advantageous Effects of Invention

As described above, according to the present invention, the heat transport layer is formed on the surface of the semiconductor chip, and the heat dissipation plate formed on the molding resin layer and the extending portion of the heat transport layer are connected by the heat transport structure penetrating the molding resin layer, so that heat dissipation can be improved without increasing the size of the package, without suppressing the degree of freedom of chip layout and wiring, and without causing malfunction or failure.

### BRIEF DESCRIPTION OF DRAWINGS

FIG. 1 is a cross-sectional view illustrating a configuration of a semiconductor device according to an embodiment of the present invention.

FIG. 2A is a cross-sectional view illustrating a state of the semiconductor device in an intermediate step for explaining a method for manufacturing the semiconductor device according to the embodiment of the present invention.

FIG. 2B is a cross-sectional view illustrating a state of the semiconductor device in an intermediate step for explaining a method for manufacturing the semiconductor device according to the embodiment of the present invention.

FIG. 2C is a cross-sectional view illustrating a state of the semiconductor device in an intermediate step for explaining a method for manufacturing the semiconductor device according to the embodiment of the present invention.

FIG. 2D is a cross-sectional view illustrating a state of the semiconductor device in an intermediate step for explaining a method for manufacturing the semiconductor device according to the embodiment of the present invention.

FIG. 2E is a cross-sectional view illustrating a state of the semiconductor device in an intermediate step for explaining the method for manufacturing the semiconductor device according to the embodiment of the present invention.

FIG. 2F is a cross-sectional view illustrating a state of the semiconductor device in an intermediate step for explaining the method for manufacturing the semiconductor device according to the embodiment of the present invention.

FIG. 2G is a cross-sectional view illustrating a state of the semiconductor device in an intermediate step for explaining the method for manufacturing the semiconductor device according to the embodiment of the present invention.

FIG. 2H is a cross-sectional view illustrating a state of the semiconductor device in an intermediate step for explaining the method for manufacturing the semiconductor device according to the embodiment of the present invention.

FIG. 2I is a cross-sectional view illustrating a state of the semiconductor device in an intermediate step for explaining the method for manufacturing the semiconductor device according to the embodiment of the present invention.

FIG. 3 is a cross-sectional view illustrating a configuration of a semiconductor device having a FOWLP structure.

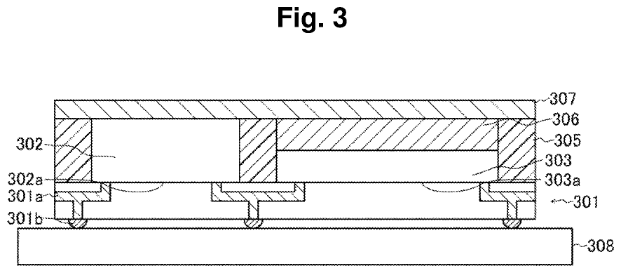

### DESCRIPTION OF EMBODIMENTS

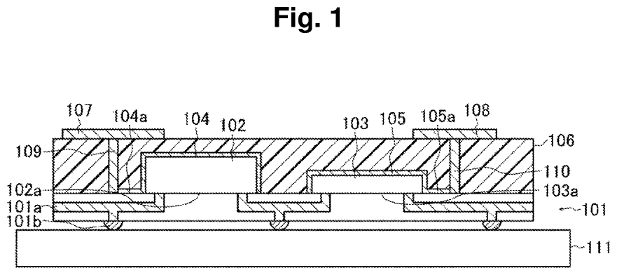

Hereinafter, a semiconductor device according to an embodiment of the present invention will be described with reference to FIG. 1. The semiconductor device includes a wiring layer 101, and a first semiconductor chip 102 and a second semiconductor chip (another semiconductor chip) 103 disposed on the wiring layer 101. The second semiconductor chip 103 may be made of a material different from the first semiconductor chip 102. For example, the first semiconductor chip 102 can be manufactured from a compound semiconductor, and the second semiconductor chip 103 can be manufactured from silicon.

Wiring 101a including metal is formed in the wiring layer 101. A first integrated circuit 102a electrically connected to the wiring 101a is formed on a main surface of the first semiconductor chip 102, the main surface facing a side of the wiring layer 101. A second integrated circuit (another integrated circuit) 103a electrically connected to the wiring 101a is formed on a main surface of the second semiconductor chip 103, the main surface facing the side of the wiring layer 101. The first integrated circuit 102a and the second integrated circuit 103a are connected to each other by the wiring 101a.

Further, the semiconductor device includes a first heat transport layer 104 formed on the first semiconductor chip 102 on the wiring layer 101. The first heat transport layer 104 is formed on a surface of the first semiconductor chip 102 on which the first integrated circuit 102a is not formed. Further, the first heat transport layer 104 includes a first extending portion 104a extending on the wiring layer 101. The first heat transport layer 104 can be formed on a part of the surface of the first semiconductor chip 102 on which the first integrated circuit 102a is not formed. Alternatively, the first heat transport layer 104 can be formed to cover the entire area of the surface of the first semiconductor chip 102 on which the first integrated circuit 102a is not formed. By covering the entire area, an effect of heat transport by the first heat transport layer 104 can be enhanced as compared with the case of covering a part thereof.

The first heat transport layer 104 includes a heat transporter. The heat transporter constituting the first heat transport layer 104 can be made of a material having a higher thermal conductivity than the first semiconductor chip 102, and can be made of, for example, a metal such as aluminum, copper, or gold. For example, in a case where the first semiconductor chip 102 is made of GaN, the heat transporter can be Cu.

Similarly, the second semiconductor chip 103 includes a second heat transport layer (another heat transport layer) 105 formed on the second semiconductor chip 103 on the wiring layer 101. The second heat transport layer 105 is formed on a surface of the second semiconductor chip 103 on which the second integrated circuit 103a is not formed. Further, the second heat transport layer 105 includes a second extending portion (another extending portion) 105a extending on the wiring layer 101. The second heat transport layer 105 can be formed on a part of the surface of the second semiconductor chip 103 on which the second integrated circuit 103a is not formed. Alternatively, the second heat transport layer 105 can be formed to cover the entire area of the surface of the second semiconductor chip 103 on which the second integrated circuit 103a is not formed. By covering the entire area, an effect of heat transport by the second heat transport layer 105 can be enhanced as compared with the case of covering a part thereof.

The second heat transport layer 105 includes a heat transporter. The heat transporter constituting the second heat transport layer 105 can be made of a material having a higher thermal conductivity than the second semiconductor chip 103, and can be made of, for example, a metal such as aluminum, copper, or gold. For example, in a case where the second semiconductor chip 103 is made of Si, the heat transporter can be Cu.

Further, the first heat transport layer 104 and the second heat transport layer 105 are formed separately (without contact) from each other on the wiring layer 101, and are formed to be insulated and separated from each other.

Further, the first semiconductor chip 102 covered with the first heat transport layer 104 and the second semiconductor chip 103 covered with the second heat transport layer 105 are molded by a molding resin layer 106 made of a molding resin on the wiring layer 101. Note that a passive component such as a resistor, a capacitor, or an inductance can be molded by the molding resin layer 106 together with the first semiconductor chip 102 and the second semiconductor chip 103.

Further, the semiconductor device includes, on the molding resin layer 106, a first heat dissipation plate 107 and a second heat dissipation plate (another heat dissipation plate) 108 formed to be separated from the first heat dissipation plate 107. The first heat dissipation plate 107 and the second heat dissipation plate 108 can include, for example, an insulating material such as silicon carbide, aluminum nitride, beryllium oxide, or diamond. Alternatively, the first heat dissipation plate 107 and the second heat dissipation plate 108 can be made of metal such as aluminum, copper, or gold.

Further, the first heat dissipation plate 107 is thermally connected to (in contact with) a columnar first heat transport structure 109 formed to penetrate the molding resin layer 106. The first heat transport structure 109 is thermally connected to (in contact with) the first extending portion 104a on the side of the wiring layer 101.

The first heat transport structure 109 includes a heat transporter. The heat transporter can be made of a material having a higher thermal conductivity than the first semiconductor chip 102. The heat transporter can be made of, for example, an insulating material such as silicon carbide, aluminum nitride, beryllium oxide, or diamond, or a metal such as aluminum, copper, or gold. For example, in a case where the first semiconductor chip 102 is made of GaN, the heat transporter can be Cu.

Similarly, the second heat dissipation plate 108 is thermally connected to (in contact with) a columnar second heat transport structure (another heat transport structure) 110 formed to penetrate the molding resin layer 106. The second heat transport structure 110 is thermally connected to (in contact with) the second extending portion 105a on the side of the wiring layer 101.

The second heat transport structure 110 includes a heat transporter. The heat transporter can be made of a material having a higher thermal conductivity than the second semiconductor chip 103. The transport structure can be made of, for example, an insulating material such as silicon carbide, aluminum nitride, beryllium oxide, or diamond, or a metal such as aluminum, copper, or gold. For example, in a case where the second semiconductor chip 103 is made of Si, the heat transporter can be Cu.

According to the semiconductor device of the above-described embodiment, heat generated in the first semiconductor chip 102 is transferred to the first heat dissipation plate 107 via the first heat transport layer 104 and the first heat transport structure 109, and diffused into the atmosphere. Further, heat generated in the second semiconductor chip 103 is transferred to the second heat dissipation plate 108 via the second heat transport layer 105 and the second heat transport structure 110, and diffused into the atmosphere.

Further, the first semiconductor chip 102, the first heat transport layer 104, the first heat transport structure 109, and the first heat dissipation plate 107 are thermally separated from the second semiconductor chip 103, the second heat transport layer 105, the second heat transport structure 110, and the second heat dissipation plate 108 by the molding resin. As a result, heat dissipation is improved while preventing a thermal interference between the semiconductor chips.

Further, although the first heat dissipation plate 107 and the second heat dissipation plate 108 are respectively attached to the first semiconductor chip 102 and the second semiconductor chip 103, the distance between the chips can be determined without depending on the size of each heat dissipation plate in plan view. In addition, it is not necessary to form wiring intended for heat dissipation in the wiring layer 101. Therefore, there is no restriction on an increase in package area, chip layout, and wiring due to wiring intended for heat dissipation.

Note that, in the semiconductor device, a terminal 101b is formed under the wiring layer 101, and the wiring layer 101 is electrically connected (mounted) to a printed circuit board 111 via the terminal 101b. In this example, secondary mounting of the FOWLP on the printed circuit board 111 by the face-down method is exemplified, but effects of the present invention can also be obtained by another method such as the face-up method of the FOWLP, or a design in which the secondary mounting is not performed.

According to the above-described embodiment, it is possible to improve the heat dissipation without increasing the size of the package, without suppressing the degree of freedom of chip layout and wiring, without causing thermal interference between the semiconductor chips having different calorific values, and without causing malfunction or failure.

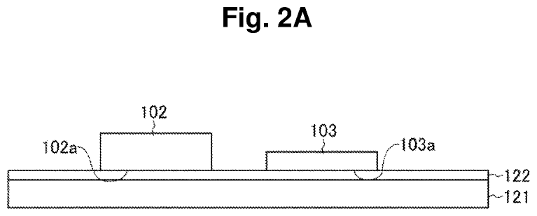

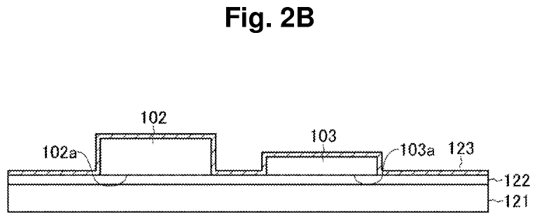

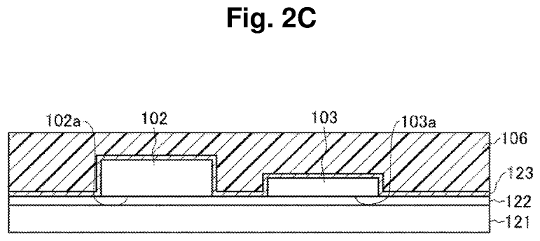

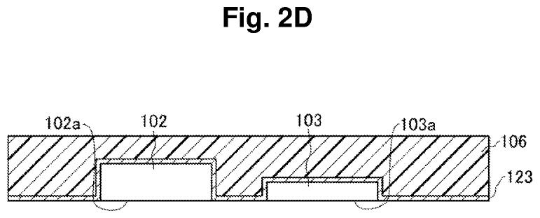

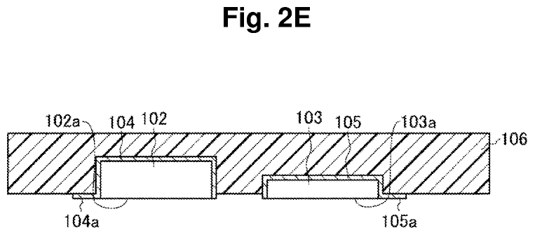

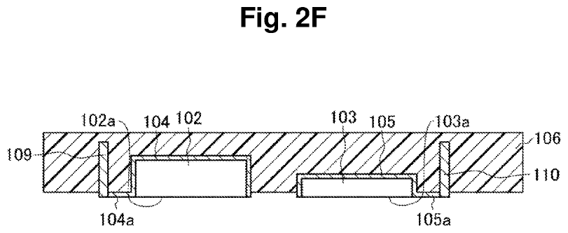

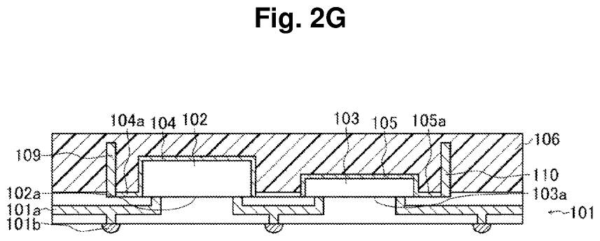

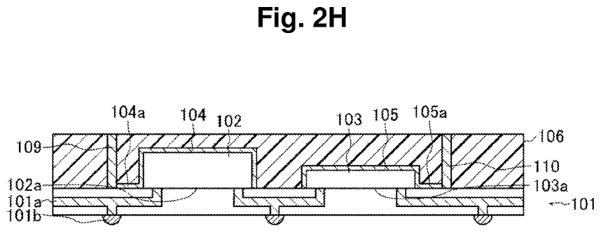

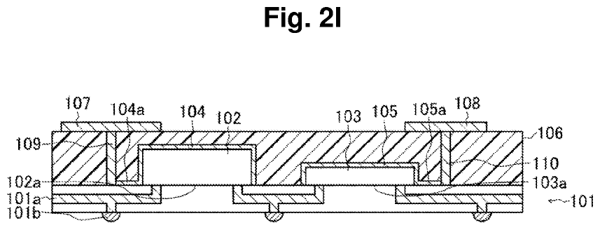

Next, a method for manufacturing the semiconductor device according to the present invention will be described with reference to FIGS. 2A to 2I. First, as illustrated in FIG. 2A, a formation surface of the first integrated circuit 102a of the first semiconductor chip 102 cut into a chip is bonded and fixed to an adhesive layer 122 fixed on a support substrate 121. Further, a formation surface of the second integrated circuit 103a of the second semiconductor chip 103 cut into a chip is bonded and fixed to the adhesive layer 122. As described above, the material of the first semiconductor chip 102 may be different from the material of the second semiconductor chip 103. Note that, although FIG. 2A illustrates one set of the first semiconductor chip 102 and the second semiconductor chip 103, a plurality of sets can be simultaneously fixed (mounted) on the support substrate 121.

The support substrate 121 may have a size corresponding to a semiconductor manufacturing apparatus used when the wiring layer 101 to be described below is formed. The material of the support substrate 121 can be, for example, a semiconductor such as silicon, glass, resin, metal, or the like. As the adhesive layer 122, a resin material whose adhesive force is weakened by a specific operation is used. For example, it is possible to select a method that does not degrade characteristics of each integrated circuit, such as a laser peeling method, a thermal peeling method, a mechanical peeling method, or a solvent peeling method. The adhesive layer 122 can be made of a material that can withstand the temperature in formation of the molding resin layer to be described below.

Next, as illustrated in FIG. 2B, a layer 123 including a heat transporter is formed on the support substrate 121 (adhesive layer 122) to which the first semiconductor chip 102 and the second semiconductor chip 103 are fixed (second step). For example, the layer 123 including a heat transporter can be formed on the support substrate 121 (adhesive layer 122) in a state of covering the first semiconductor chip 102 and the second semiconductor chip 103. The layer 123 can be formed by, for example, a known sputtering method or the like.

Note that the layer 123 is formed by sputtering or the like with a lift-off mask formed in advance, and then the lift-off mask is removed (lifted off), so that the layer 123 can be formed on a part of the surface of the first semiconductor chip 102 on which the first integrated circuit 102a is not formed and a part of the surface of the second semiconductor chip 103 on which the second integrated circuit 103a is not formed.

Next, as illustrated in FIG. 2C, after the layer 123 is formed, the first semiconductor chip 102 is molded with the molding resin on the support substrate 121 (adhesive layer 122) to form the molding resin layer 106 (third step). The molding resin layer 106 can be formed by, for example, forming a layer of the molding resin by a known compression molding method, transfer molding method, or the like and curing the formed layer of the molding resin.

Next, the molding resin layer 106 is separated from the support substrate 121 (fourth step), and an integrated circuit formation surface is exposed as illustrated in FIG. 2D. For example, by peeling off the adhesive layer 122, the molding resin layer 106 can be separated from the support substrate 121. For example, it is possible to select a method that does not degrade characteristics of each integrated circuit, such as a laser peeling method, a thermal peeling method, a mechanical peeling method, or a solvent peeling method.

Next, after the support substrate 121 and the molding resin layer 106 are separated, as illustrated in FIG. 2E, the first heat transport layer 104 including the first extending portion 104a and the second heat transport layer 105 including the second extending portion 105a are formed. For example, the first heat transport layer 104 can cover the surface of the first semiconductor chip 102 other than the surface on the side where the first integrated circuit 102a is formed. Further, the second heat transport layer 105 can cover the surface of the second semiconductor chip 103 other than the surface on the side where the second integrated circuit 103a is formed.

In a case where the layer 123 is formed on a part of the surface of the first semiconductor chip 102 on which the first integrated circuit 102a is not formed, the first heat transport layer 104 is formed on a part of the surface of the first semiconductor chip 102 on which the first integrated circuit 102a is not formed. Similarly, in a case where the layer 123 is formed on a part of the surface of the second semiconductor chip 103 on which the second integrated circuit 103a is not formed, the second heat transport layer 105 is formed on a part of the surface of the second semiconductor chip 103 on which the second integrated circuit 103a is not formed.

For example, the first heat transport layer 104 including the first extending portion 104a can be formed by removing a part of the layer 123 formed to cover the back surface of the molding resin layer 106 on the side where the first integrated circuit 102a is formed by selective (partial) etching processing using a mask pattern formed by a known photolithography technique. Further, the second heat transport layer 105 including the second extending portion 105a can be formed by removing a part of the layer 123 formed to cover the back surface of the molding resin layer 106 on the side where the second integrated circuit 103a is formed by the selective etching processing using a mask pattern.

Next, as illustrated in FIG. 2F, the first heat transport structure 109 including a heat transporter thermally connected to the first extending portion 104a of the first heat transport layer 104 is formed in a state of being molded in the molding resin layer 106. Further, the second heat transport structure 110 including a heat transporter thermally connected to the second extending portion 105a of the second heat transport layer 105 is formed in a state of being molded in the molding resin layer 106 (sixth step).

For example, a hole is formed in the molding resin layer 106 by a laser or the like, and a metal such as copper is filled in the formed hole by a plating method or the like, whereby the first heat transport structure 109 and the second heat transport structure 110 can be formed.

Note that, in the case of using the insulating material such as silicon carbide, aluminum nitride, beryllium oxide, or diamond as the heat transporter, the above-described plating method cannot be applied. In this case, the first heat transport structure 109 and the second heat transport structure 110 are formed (bonded) in a stage where the formation surface of the first integrated circuit 102a of the first semiconductor chip 102 is bonded and fixed on the support substrate 121, and the formation surface of the second integrated circuit 103a of the second semiconductor chip 103 is bonded and fixed. In this state, the layer 123 is formed, the molding resin layer 106 is formed, the support substrate 121 is separated, and the first heat transport layer 104 and the second heat transport layer 105 are formed. As a result, the first heat transport structure 109 can be connected to (in contact with) the first extending portion 104a, and the second heat transport structure 110 can be connected to (in contact with) the second extending portion 105a in the state of being molded in the molding resin layer 106.

Next, as illustrated in FIG. 2G, the first semiconductor chip 102 and the second semiconductor chip 103 are formed (mounted) on the wiring layer 101 including the wiring 101a. The first integrated circuit 102a and the second integrated circuit 103a are connected to the wiring 101a. Further, the first semiconductor chip 102 and the second semiconductor chip 103 are molded with the molding resin layer 106 on the wiring layer 101 (seventh step).

For example, the wiring layer 101 can be formed on the first semiconductor chip 102 and the second semiconductor chip 103 molded with the molding resin layer 106 by a build-up method. For example, after the first semiconductor chip 102 and the second semiconductor chip 103 are molded with the molding resin layer 106, a metal layer is formed on the molding resin layer 106 by, for example, vapor deposition or a plating method, and the metal layer is patterned, whereby the wiring 101a can be formed into the wiring layer 101. Further, the terminal 101b connected to the wiring 101a is formed in the wiring layer 101 by, for example, a solder bump or the like.

Next, as illustrated in FIG. 2H, the molding resin layer 106 is thinned so that an upper surface of the first heat transport structure 109 and an upper surface of the second heat transport structure 110 are exposed. For example, the upper surface of the first heat transport structure 109 and the upper surface of the second heat transport structure 110 are exposed by mechanically polishing (grinding and polishing) the surface of the molding resin layer 106 with a grinder or the like.

Next, as illustrated in FIG. 2I, the first heat dissipation plate 107 thermally connected to the first heat transport structure 109 and the second heat dissipation plate 108 thermally connected to the second heat transport structure 110 are formed on the thinned molding resin layer 106 (eighth step). For example, a layer of a metal such as aluminum, copper, or gold is formed on the thinned molding resin layer 106 by a plating method or the like. Next, the first heat dissipation plate 107 and the second heat dissipation plate 108 can be formed by patterning the formed metal layer by a known photolithography technique and etching technique.

Thereafter, a dicing device is used to dice the substrate into an individual piece for each set of the first semiconductor chip 102 and the second semiconductor chip 103. Thereafter, the semiconductor device illustrated in FIG. 1 is obtained by mounting the individual set of the first semiconductor chip 102 and the second semiconductor chip 103 onto the printed circuit board 111 via the terminal 101b of the package by the set. For example, in a case where a solder bump is used, the mounting can be performed by a known reflow technique.

As described above, according to the present invention, the heat transport layer is formed on the surface of the semiconductor chip, and the heat dissipation plate formed on the molding resin layer and the extending portion of the heat transport layer are connected by the heat transport structure penetrating the molding resin layer, so that heat dissipation can be improved without increasing the size of the package, without suppressing the degree of freedom of chip layout and wiring, and without causing malfunction or failure.

Note that the present invention is not limited to the embodiment described above, and it is obvious that many modifications and combinations can be made by those skilled in the art within the technical idea of the present invention.

### REFERENCE SIGNS LIST

101 Wiring layer
101a Wiring
101b Terminal
102 First semiconductor chip
102a First integrated circuit
103 Second semiconductor chip (another semiconductor chip)
103a Second integrated circuit (another integrated circuit)
104 First heat transport layer
104a First extending portion
105 Second heat transport layer (another heat transport layer)
105a Second extending portion (another extending portion)
106 Molding resin layer
107 First heat dissipation plate
108 Second heat dissipation plate (another heat dissipation plate)
109 First heat transport structure
110 Second heat transport structure (another heat transport structure)
111 Printed circuit board

1. A semiconductor device comprising:
a wiring layer in which wiring is formed;
a semiconductor chip disposed on the wiring layer;
an integrated circuit formed on a main surface of the semiconductor chip, the main surface facing a side of the wiring layer, and connected to the wiring;
a heat transport layer formed on a surface of the semiconductor chip on which the integrated circuit is not formed, and further including a heat transporter including an extending portion extending on the wiring layer and formed on the semiconductor chip;
a molding resin layer made of a molding resin for molding the semiconductor chip covered with the heat transport layer on the wiring layer;
a heat dissipation plate formed on the molding resin layer; and
a heat transport structure formed to penetrate the molding resin layer, and including a heat transporter that thermally connects the extending portion of the heat transport layer and the heat dissipation plate.

2. The semiconductor device according to claim 1, further comprising:
another semiconductor chip different from the semiconductor chip and disposed on the wiring layer;
another integrated circuit formed on a main surface of the another semiconductor chip, the main surface facing the side of the wiring layer, and connected to the wiring;
another heat transport layer formed on a surface of the another semiconductor chip on which the another integrated circuit is not formed, and further including a heat transporter including another extending portion extending on the wiring layer and formed on the another semiconductor chip;
the molding resin layer for molding the another semiconductor chip covered with the another heat transport layer on the wiring layer;
another heat dissipation plate formed to be separated from the heat dissipation plate on the molding resin layer; and
another heat transport structure formed to penetrate the molding resin layer, and including a heat transporter that thermally connects the another extending portion of the another heat transport layer and the another heat dissipation plate.

3. The semiconductor device according to claim 2, wherein
a material of the semiconductor chip is different from a material of the another semiconductor chip.

4. A method of manufacturing a semiconductor device comprising:
a first step of fixing a semiconductor chip having an integrated circuit formed on a main surface onto a support substrate with the surface on which the integrated circuit is formed;
a second step of forming a layer including a heat transporter on the support substrate to which the semiconductor chip is fixed;
a third step of forming a layer including a heat transporter on the support substrate and then molding the semiconductor chip with a molding resin to form a molding resin layer;
a fourth step of separating the support substrate and the molding resin layer;
a fifth step of separating the support substrate and the molding resin layer, then removing a part of the layer formed to cover a back surface of the molding resin layer on a side where the integrated circuit is formed, and forming a heat transport layer including an extending portion formed on a surface of the semiconductor chip other than the surface on the side where the integrated circuit is formed and further extending on the back surface of the molding resin layer;
a sixth step of forming a heat transport structure including a heat transporter thermally connected to the extending portion of the heat transport layer in a state of being molded in the molding resin layer;
a seventh step of forming a state in which the semiconductor chip is disposed on a wiring layer including wiring, the integrated circuit is connected to the wiring, and the semiconductor chip is molded with the molding resin layer on the wiring layer; and
an eighth step of forming a heat dissipation plate thermally connected to the heat transport structure on the molding resin layer.

5. The method of manufacturing a semiconductor device according to claim 4, wherein
the first step includes a step of fixing another semiconductor chip having another integrated circuit formed on a main surface onto the support substrate with the surface on which the another integrated circuit is formed,
the second step includes a step of forming the layer including a heat transporter on the support substrate to which the semiconductor chip and the another semiconductor chip are fixed,
the third step includes a step of molding the semiconductor chip and the another semiconductor chip with a molding resin to form the molding resin layer,
the fifth step includes a step of separating the support substrate and the molding resin layer, then removing a part of the layer formed to cover the back surface of the molding resin layer on a side where the another integrated circuit is formed, and forming another heat transport layer formed on a surface of the another semiconductor chip other than the surface on the side where the another integrated circuit is formed and further including another extending portion extending on the back surface of the molding resin layer,
the sixth step includes a step of forming another heat transport structure including a heat transporter thermally connected to the another extending portion of the another heat transport layer in a state of being molded in the molding resin layer,
the seventh step includes a step of forming a state in which the another semiconductor chip is disposed on the wiring layer, the another integrated circuit is connected to the wiring, and the another semiconductor chip is molded with the molding resin layer on the wiring layer, and
the eighth step includes a step of forming another heat dissipation plate thermally connected to the another heat transport structure so as to be separated from the heat dissipation plate on the molding resin layer.

6. The method of manufacturing a semiconductor device according to claim 5, wherein
a material of the semiconductor chip is different from a material of the another semiconductor chip.
